(19) United States
(12) Patent Application Publication
(10) Pub. No.: US 2010/0127715 A1
(43) Pub. Date: May 27, 2010

(54) SEMICONDUCTOR PHYSICAL QUANTITY SENSOR AND CONTROL DEVICE USING THE SAME

(75) Inventors: Heewon JEONG, Tokyo (JP); Kiyoko YAMANAKA, Tachikawa (JP)

Correspondence Address: MILES & STOCKBRIDGE PC, 1751 PINNACLE DRIVE, SUITE 500, MCLEAN, VA, 22102-3833, US

(73) Assignee: HITACHI, LTD.

(21) Appl. No.: 12/622,549

(22) Filed: Nov. 20, 2009

(30) Foreign Application Priority Data
Nov. 27, 2008 (JP) 2008-302639

(51) Int. Cl. G01R 27/26; H01G 5/00

(52) U.S. Cl. 324/661; 361/277

(57) ABSTRACT

A highly reliable semiconductor physical quantity sensor whose performance does not change much over time is provided. In the semiconductor physical quantity sensor, movable electrodes which can be displaced by applying a physical quantity are initially displaced using an electrostatic force, and the movable electrodes are used to detect the direction and magnitude of a physical quantity applied to the semiconductor physical quantity sensor. The semiconductor physical quantity sensor is highly reliable and its performance does not change much over time compared with semiconductor physical quantity sensors using a known method in which movable electrodes are initially displaced using a compressive stress film.

### CLAIM OF PRIORITY

The present application claims priority from Japanese Patent Application JP 2008-302639 filed on Nov. 27, 2008, the content of which is hereby incorporated by reference into this application.

### FIELD OF THE INVENTION

The present invention relates to a semiconductor physical quantity sensor and a control device using the same. More particularly, the invention relates to a semiconductor physical quantity sensor which is formed using fine fabrication technology for semiconductors (i.e. MEMS process) and which measures a physical quantity, for example, acceleration or an angular rate by detecting a physical quantity associated with an inertial force generated in a vibrating object and a control device using such a semiconductor physical quantity sensor.

### BACKGROUND OF THE INVENTION

There have been known semiconductor physical quantity sensors each of which includes a movable microelectrode formed by removing a sacrifice layer on a silicon substrate and a fixed electrode facing the movable electrode and forming electrostatic capacitance between itself and the movable electrode and which detects a change in a physical quantity based on a change in the electrostatic capacitance between the electrodes.

According to a semiconductor physical quantity sensor and a method for manufacturing the same disclosed in Japanese Patent Application Laid-Open publication No. 2006-84326, a capacitance type angular rate sensor includes a movable electrode and a fixed electrode located opposite to the movable electrode, which are formed on a support substrate of silicon. In the semiconductor physical quantity sensor, a compressive stress layer is formed on the surface of a beam suspending the movable electrode thereby causing the movable electrode to be cambered away from the support substrate. The movable electrode cambered away from the support substrate faces the fixed electrode in a position more shifted, than the fixed electrode, from the support substrate.

When a physical quantity is applied to the sensor in the thickness direction of the support substrate causing the movable electrode to be displaced away from the support substrate, the area of each of the mutually facing surface portions of the movable electrode and the fixed electrode for physical quantity detection decreases causing the capacitance between the electrodes to decrease.

When, on the other hand, a physical quantity is applied to the sensor in the thickness direction of the support substrate causing the movable electrode to be displaced toward the support substrate, the area of each of the mutually facing surface portions of the movable electrode and the fixed electrode for physical quantity detection increases causing the capacitance between the electrodes to increase.

Thus, detecting the direction and magnitude of a capacitance change between the movable electrode and the fixed electrode makes it possible to appropriately detect the direction and magnitude of displacement of the movable electrode in the thickness direction of the support substrate, i.e. the direction and magnitude of a physical quantity applied to the sensor. According to Japanese Patent Application Laid-Open Publication No. 2006-84326, the compressive stress layer is formed of thermally-oxidized film, polysilicon film, or silicon nitride film.

### SUMMARY OF THE INVENTION

As described above, in the semiconductor physical quantity sensor according to Japanese Patent Application laid-Open Publication No. 2006-84326, a compressive stress layer is formed on the surface of a beam causing the movable electrode to be cambered away from the support substrate. This makes it possible to appropriately detect the direction and magnitude of a change in displacement, in the thickness direction of the support substrate, of the movable electrode, i.e. the direction and magnitude of a physical quantity applied to the sensor.

There are, however, the following problems with the existing technology disclosed in Japanese Patent Application Laid-Open Publication No. 2006-84326.
(1) Forming the compressive stress layer on the surface of a beam requires a complicated process to be performed, resulting in a high fabrication cost.
(2) Forming a thermally-oxidized film, polysilicon film, or silicon nitride film requires a high-temperature process to be performed involving a temperature ranging from several hundred degrees to several thousand degrees Celsius. This restricts integrating a capacitance-voltage conversion circuit near the fixed electrode or the movable electrode for the purpose of enhancing the performance, for example, detection sensitivity of the sensor.
(3) The internal stress of the compressive stress layer largely varies depending on the temperature and with the passage of time, possibly making the sensor less reliable.
(4) The internal stress of the compressive stress layer causes, depending on the layer film thickness, large variations in sensor performance related with, for example, internal sensitivity and the initial offset state of the electrodes.
(5) The degree of cambering of the movable electrode is dependent on conditions involved in the process for forming the compressive stress layer, and it cannot be actively controlled. Therefore, adjusting the sensor performance requires complicated signal processing to be performed.

The present invention has been made in view of the above problems with the existing technology, and it is an object of the invention to provide a low-cost physical quantity sensor with high sensitivity and high reliability and a control device using the physical quantity sensor.

The above and other objects and novel characteristics of the present invention will be apparent from the description of this specification and the accompanying drawings.

A typical structure of the present invention is as follows. The semiconductor physical quantity sensor includes a movable electrode which is displaced when a physical quantity is applied and a fixed electrode which faces the movable electrode and forms electrostatic capacitance. The semiconductor physical quantity sensor detects, when a physical quantity is applied thereto, the physical quantity according to an electrostatic capacitance change caused between the movable electrode and the fixed electrode. In the semiconductor physical quantity sensor: the movable electrode and the fixed electrode are formed on a same conductive layer having a substantially uniform height on a substrate; and the movable electrode and the fixed electrode are placed, using an electrostatic force, in an initial offset state where the movable electrode and the fixed electrode have different distances to the substrate.

According to the present invention, a highly reliable semiconductor physical quantity sensor whose performance does not change much over time and a control device using the physical quantity sensor are provided.

### BRIEF DESCRIPTION OF THE DRAWINGS

FIG. 1 is a plan view showing the structure of an acceleration sensor according to a first embodiment of the present invention;

FIG. 2 is a sectional view taken along line A-A′ in FIG. 1;

FIG. 3A is a schematic view showing an effect of shifting a movable electrode and a fixed electrode according to the first embodiment of the invention.

FIG. 3B is an enlarged view of a portion including electrodes of FIG. 3A;

FIG. 3C is a sectional view taken along line A-A′ in FIG. 1 with the sensor covered with a cap;

FIG. 4 is a view of the acceleration sensor in a mounted state according to the first embodiment of the invention;

FIG. 5A is a diagram for explaining the operation of the acceleration sensor according to the first embodiment of the invention;

FIG. 5B is a diagram for explaining the operation of the acceleration sensor according to the first embodiment of the invention;

FIG. 5C is a diagram for explaining the operation of the acceleration sensor according to the first embodiment of the invention;

FIG. 6A is a conceptual diagram of the acceleration sensor and a signal processing IC having a detection circuit according to the first embodiment of the invention;

FIG. 6B shows relationships, in the control circuit shown in FIG. 6A, among the direction and magnitude of acceleration A applied, displacement d, and capacitance change ΔC;

FIG. 6C shows a relationship, in the control circuit shown in FIG. 6A, between the direction and magnitude of acceleration A applied and output voltage Vo′;

FIG. 7 is a plan view showing the structure of an acceleration sensor according to a third embodiment of the invention;

FIG. 8 is a sectional view taken along line B-B′ in FIG. 7;

FIG. 9 is a conceptual diagram of the acceleration sensor and a signal processing IC having a detection circuit according to the third embodiment of the invention;

FIG. 10 is a schematic view showing an effect of shifting a movable electrode and a fixed electrode according to the third embodiment of the invention;

FIG. 11 is a view of the acceleration sensor in a mounted state according to the third embodiment of the invention;

FIG. 12A is a diagram for explaining the operation of the acceleration sensor according to the third embodiment of the invention;

FIG. 12B is a diagram for explaining the operation of the acceleration sensor according to the third embodiment of the invention; and

FIG. 12C is a diagram for explaining the operation of the acceleration sensor according to the third embodiment of the invention.

### DETAILED DESCRIPTION OF THE PREFERRED EMBODIMENTS

The physical quantity sensor according to a typical embodiment of the present invention includes a movable electrode which is displaced when a physical quantity is applied and a fixed electrode which faces the movable electrode and forms electrostatic capacitance. The semiconductor physical quantity sensor detects, when a physical quantity is applied thereto, the physical quantity according to an electrostatic capacitance change caused between the movable electrode and the fixed electrode. In the semiconductor physical quantity sensor, the movable electrode and the fixed electrode are formed on a same layer, and they are shifted using an electrostatic force such that they have different distances to the substrate.

According to the invention, when an electrostatic force is applied to the movable electrode in the substrate thickness direction (in the direction toward outside the sensor surface), the distance between the movable electrode and the support substrate changes, causing the movable electrode and the fixed electrode fixed to the support substrate to be shifted from each other in the substrate thickness direction.

Based on the positional relationship between the movable electrode and the fixed electrode being shifted from each other, the magnitude and direction of a physical quantity applied in the same direction can be appropriately detected.

The physical quantity sensor of the present invention can be fabricated by preparing a multi-layer substrate including a support substrate on which a conductive layer (active layer) is formed via, in the substrate thickness direction, an interlayer insulation layer; movably connecting a movable electrode formed in the active layer to the support substrate via the interlayer insulation layer; and fixing a fixed electrode formed also in the active layer to the support substrate. The multi-layer substrate may be a silicon-on-insulator substrate (i.e. an SOI wafer) including the support substrate and the active layer both formed of silicon and the insulation layer formed of silicon oxide film.

In the SOI wafer, when a bias voltage is applied to between the active layer on which the movable electrode is formed and the support substrate, the movable electrode suspended by the support substrate via the interlayer insulation layer can be pulled toward the support substrate to be displaced in the substrate thickness direction. Such a sensor structure can be realized without requiring a complicated fabrication process.

The physical quantity sensor according to another embodiment of the present invention includes a multi-layer substrate having a glass or silicon cap disposed thereon and, in the physical quantity sensor, the movable electrode is displaced away from the support substrate by applying a bias voltage to between the cap and the movable electrode. According to the embodiment, the movable electrode is displaced away from the support substrate, so that the displacement is not restricted by the thickness of the interlayer insulation layer or by any pull-in phenomenon. It is therefore possible to reduce the initial capacitance C0 between the movable electrode and the fixed electrode while maintaining the capacitance change (ΔC) caused by a physical quantity applied to the sensor. This makes it possible to detect the applied physical quantity with high sensitivity and high accuracy.

The physical quantity sensor according to still another embodiment of the present invention includes a bias voltage adjusting unit which can actively adjust the amount of shifting between the fixed electrode and the movable electrode. This makes it possible, for example, to adjust the shifting between the electrodes according to a range of physical quantity measurement or to adjust, relative to another physical quantity sensor, the sensor sensitivity or initial output (sensor output with an initial capacitance C0) by adjusting the shifting between the electrodes.

As described above, the invention is suitable for application mainly to acceleration sensors or angular rate sensors with a detection axis extending in the support substrate thickness direction (the direction toward outside the sensor surface).

In the physical quantity sensor according the present invention, the fixed electrode and the movable electrode are shifted from each other using an electrostatic force. The effects of the arrangement are summarized in the following.
(1) A movable electrode which can be displaced by applying a physical quantity is initially displaced using an electrostatic force. Since no compressive stress layer is required, a general-purpose SOI wafer can be adopted. It is therefore possible to use a simple fabrication process, resulting in a low cost and a high yield.
(2) With no compressive stress layer required, a fabrication process involving lower temperature than before can be adopted, making it easier to integrate the sensor together with peripheral circuits, for example, a C-V conversion circuit. For fabrication, different types of processes can be flexibly combined making it possible to provide low-cost, high-performance semiconductor physical quantity sensors.
(3) Since an SOI substrate is used, a process for bonding a support substrate is not required. The SOI substrate can be hermetically sealed just by bonding a cap to it once, so that a high process yield can be achieved while enhancing the bonding process reliability. Hence, low-cost, high-performance semiconductor physical quantity sensors can be provided.
(4) With the method of the present invention in which the movable electrode is displaced using an electrostatic attractive force, sensor characteristic variations caused by temperature changes or resulting from the passage of time are smaller than with the existing method in which a compressive stress layer is used to displace a movable electrode. The semiconductor physical quantity sensor according to the present invention can therefore be used for long periods of time by having such characteristic variations periodically (for example, once in several years) corrected by adjusting the bias voltage used to generate the electrostatic attractive force. Thus, the semiconductor physical quantity sensor is effective for applications, for example, automobile attitude control which is required to display highly reliable performance over long periods of time, say, for 20 years or more.
(5) Whereas the compressive stress layer characteristics are expected to vary from wafer to wafer, the method according to the present invention in which an electrostatic attractive force is used allows the electrostatic force to be adjusted individually. This makes it possible to achieve a high fabrication yield which leads to a low fabrication cost.
(6) As being described in detail as an embodiment in the following, the method in which an electrostatic attractive force is used makes it possible to adjust, by adjusting the bias voltage, the initial capacitance C0 between the movable electrode and the fixed electrode while maintaining the capacitance change (ΔC) caused by a physical quantity to be detected. The method makes it possible to remove variations, between plural semiconductor physical quantity sensors, in sensitivity and in the initial shifting of the electrodes. Hence, highly reliable semiconductor physical quantity sensors can be provided with a high yield (at a low cost).
(7) Using the function to adjust the bias voltage, a physical quantity range to be measured can be actively determined. The measurement range of an acceleration sensor can, therefore, be switched, for example, between ±2 G and ±4 G just by changing the bias voltage.

The present invention can be applied to a semiconductor physical quantity sensor such as an acceleration sensor or an angular rate sensor. Such sensor can applicable as a speed sensor or an inclination angle sensor. A control device using a semiconductor physical quantity sensor according to the present invention can be used in a large variety of products including an automobile, portable appliances, amusement apparatus, and home information appliances. In the field of the automobile, for example, a device or a system to which the control device can be applied include a travel speed control device, an air-bag system, an attitude control system for stabilizing automobile attitude during a turn, or a navigation system.

Embodiments of the present invention will be described below with reference to drawings. In the following, the description of the invention will be divided into two or more sections or will range over two or more embodiments as required for the sake of convenience. Unless otherwise expressed, such sections and embodiments are not mutually irrelevant. For example, among such sections and embodiments, one is a partial or total modification of another, or one elaborates or supplements another.

Also, numbers referred to in the following description of embodiments (for example, numbers representing counts, amounts, ranges, or other numeric values) are not defined values, that is, they may be smaller or larger unless otherwise expressed or except when they are apparently defined in principle.

Furthermore, the constituent elements (including element steps) of the following embodiments are not necessarily indispensable unless otherwise expressed or except when they are apparently indispensable in principle.

Similarly, the shapes of and positional relationships between constituent elements referred to in the following description are inclusive of those substantially close to or similar to them unless otherwise expressed or except when such shapes and positional relationships are apparently considered strictly defined in principle. This also applies to the numeric values and ranges.

Note that, in the drawings referred to in describing the following embodiments, identical members are denoted, as a rule, by identical reference numerals, and duplicate descriptions of identical members are omitted. Also note that the drawings referred to in the following may include plan views hatched to make them clearer.

### First Embodiment

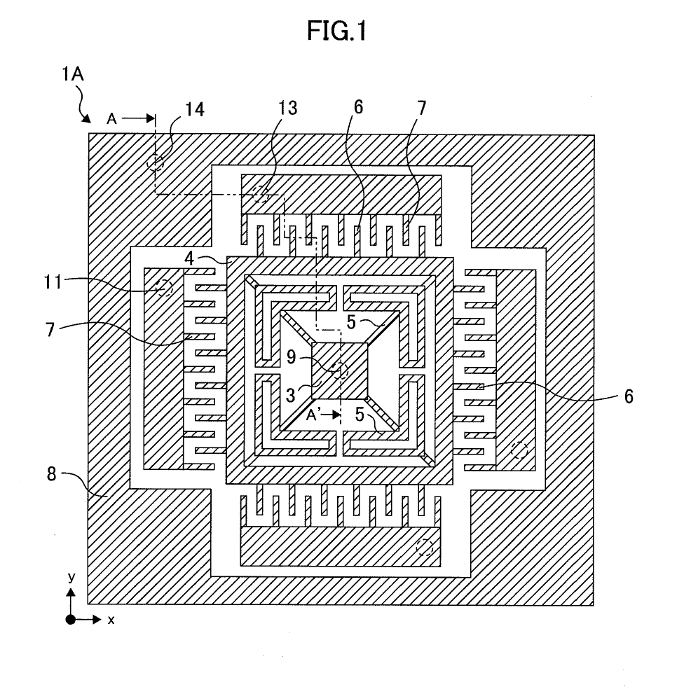

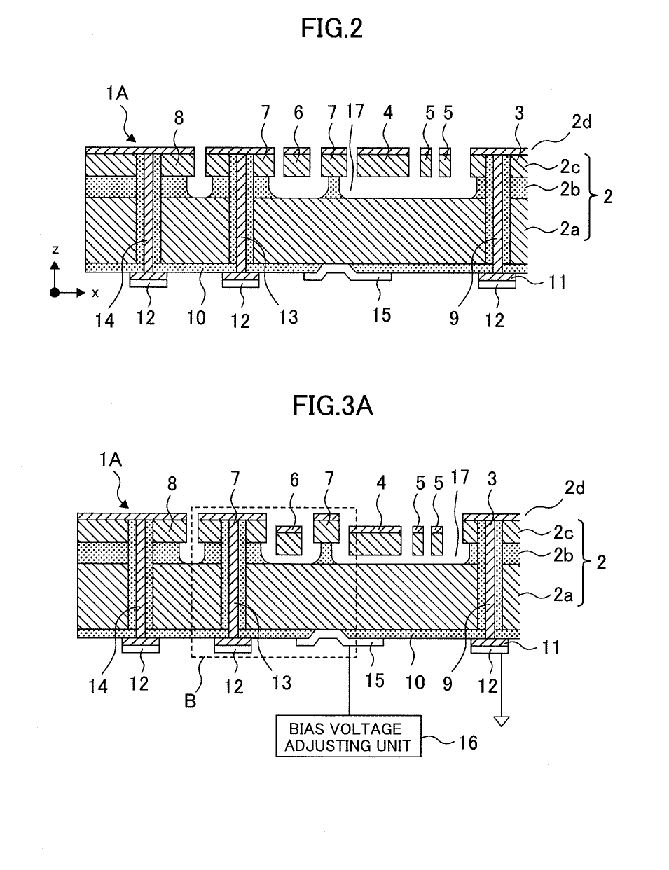

A semiconductor physical quantity sensor according to a first embodiment of the present invention will be described with reference to FIGS. 1 to 6C. The semiconductor physical quantity sensor of the first embodiment is an acceleration sensor for detecting acceleration as a physical quantity. With reference to the drawings, the structure, manufacturing method, and the principle of operation of an acceleration sensor 1A will be described in detail below. FIG. 1 is a schematic diagram showing a plan view of principal constituent elements of the acceleration sensor 1A of the first embodiment. FIG. 2 shows a sectional view taken along line A-A′ in FIG. 1.

First, the structure of the acceleration sensor 1A of the first embodiment will be described. The acceleration sensor 1A includes, for example, a silicon-on-insulator (SOI) substrate 2 (See FIG. 2). The SOI substrate 2 includes a support substrate 2a, an interlayer insulation layer 2b formed over the support substrate 2a, and a conductive layer (active layer) 2c formed over the interlayer insulation layer 2b. The support substrate 2a is formed of, for example, silicon (Si). The interlayer insulation layer 2b is formed of, for example, silicon oxide (SiO₂). The conductive layer 2c formed over the interlayer insulation layer 2b and the connecting conductive layer 2d formed over the conductive layer 2c are each formed of, for example, conductive silicon (e.g. doped silicon or low-resistance silicon).

The thickness of the stack structure of the SOI substrate 2, i.e. the total thickness of the support substrate 2a and the interlayer insulation layer 2b, may range, for example, from several tens of micrometers to several hundreds micrometers. The conductive layer 2c ranges, for example, from several micrometers to several tens of micrometers in thickness. Even though, in the first embodiment, the SOI substrate 2 is used as a semiconductor substrate, the semiconductor substrate need not necessarily be an SOI substrate. The semiconductor substrate may be formed of, for example, conductive polysilicon obtained using surface MEMS (microelectromechanical system) technology. Also, the stack structure may include a conductive layer of, for example, plated nickel.

As shown in FIGS. 1 and 2, a fixed part 3 is formed by patterning the active layer 2c. The fixed part 3 is fixed to the support substrate 2a via the interlayer insulation layer 2b. The fixed part 3 is connected with a beam 5 to support a mass body 4 which is displaced when subjected to acceleration. The beam 5 is formed to be flexible outwardly of the sensor surface (in the z direction of FIG. 2) and rigid in the in-plane directions (in the x-y plane of FIG. 1), so that it is displaced responding to acceleration applied to the mass body 4 outwardly of the sensor surface (in the z direction). Referring to FIG. 1, the beam 5 has four arms extending from the fixed part 3 radially outwardly to the mass body 4 and a pair of laterally extending rectangular parts connected to an intermediate portion of each of the four arms. The beam 5 need not necessarily be shaped as shown in FIG. 1 as long as it is flexible outwardly of the sensor surface and rigid in the in-plane directions.

The mass body 4 has movable electrodes 6 which formed to be displaced together with the mass body 4. Namely, the movable electrodes 6 formed integrally with the mass body 4 are held by the fixed part 3 via the beam 5 that is displaced responding to acceleration applied outwardly of the sensor surface. The active layer 2c also includes fixed electrodes 7 formed such that capacitance is formed between the movable electrodes 6 and the fixed electrodes 7. Namely, the movable electrodes 6 and the fixed electrodes 7 are formed in the conductive layer 2c to be substantially at the same height over, via the interlayer insulation layer 2b, the support substrate. Since the fixed electrodes 7 are fixed to the support substrate 2a via the interlayer insulation layer 2b, they are not displaced even when subjected to acceleration. The movable electrodes 6 and the fixed electrodes 7 are positioned like pairs of mutually facing combs whose teeth appear engaged with opposing ones without mutually touching so as to increase the electrostatic capacitance formed between their mutually facing surface portions.

The fixed electrodes 7 are surrounded by a dummy pattern 8 whose potential is fixed to the reference voltage (DC voltage) of the mass body 4 so as to shield against external electromagnetic noise and reduce processing fluctuations during DRIE (deep reactive ion etching).

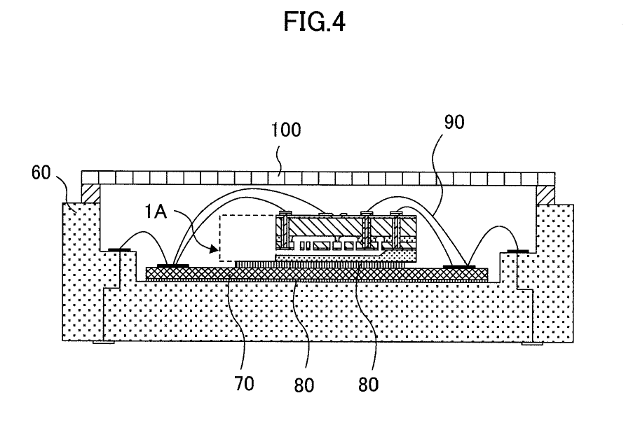

The fixed part 3 is used also as an electrode for providing the movable electrodes 6 with electrical signals. Electrical signals received from outside are applied to the movable electrodes 6 via a through-electrode 9 connected to the fixed part 3 as being described later with reference to FIG. 4.

To form the through-electrode 9, first a through hole is formed in the support substrate 2a; a thermally oxidized insulation film 10 is formed over the support substrate 2a thereby insulating the through hole; and the insulated through hole is filled with a polysilicon film 11 to diffuse impurities and thereby lower the insulation resistivity of the through-electrode 9. The polysilicon film 11 is attached with a metal electrode pad 12 of, for example, aluminum which is used to exchange, via a bonded wire, signals with an external signal processing unit (e.g. an LSI).

Like the movable electrode 6, each of the fixed electrodes 7 is also provided with a through-electrode 13 and a pad 12. The fixed electrode 7 exchanges signals with the outside via the through-electrode 13.

The dummy pattern 8 is also provided with a through-electrode 14 and a pad 12, so that the dummy pattern 8 can be held at a predetermined potential.

The connecting conductive layer 2d is formed to electrically connect the through-electrode 9, the fixed part 3, the beam 5, and the movable electrodes 6. The connecting conductive layer 2d is also formed to electrically connect the through-electrodes 13, the fixed electrodes 7, and the through-electrode 14 to the peripheral dummy pattern 8. The fixed part 3 is formed by patterning the active layer 2c and the connecting conductive layer 2d. Subsequently, a gap 17 is formed by removing a sacrifice layer (a part of the interlayer insulation layer 2b).

A substrate electrode 15 is formed on the support substrate 2a. The substrate electrode 15 is formed, for example, by processing the thermally oxidized film 10 by photolithography, then forming an aluminum film by sputtering, and patterning the aluminum film. The substrate electrode 15 makes up a part of a bias voltage applying unit. The bias voltage applying unit applies a bias voltage to the substrate electrode 15 and places, using an electrostatic force, the movable electrodes 6 and the fixed electrodes 7 in an initial offset state where the distance between the movable electrodes 6 and the support substrate 2a differs from the distance between the fixed electrodes 7 and the support substrate 2a.

Principal constituent elements of the acceleration sensor 1A such as the fixed part 3, the mass body 4, the beam 5, the movable electrodes 6, the fixed electrodes 7, and the peripheral dummy pattern 8 need not necessarily be shaped and arranged as shown in FIG. 1. They may be arranged in an arbitrary pattern. For example, the movable electrodes 6 may be arranged to be held by the fixed part 3 at both ends. Depending on the application, the acceleration sensor 1A may be formed in a laminate structure formed on an ordinary silicon substrate instead of an SOI substrate.

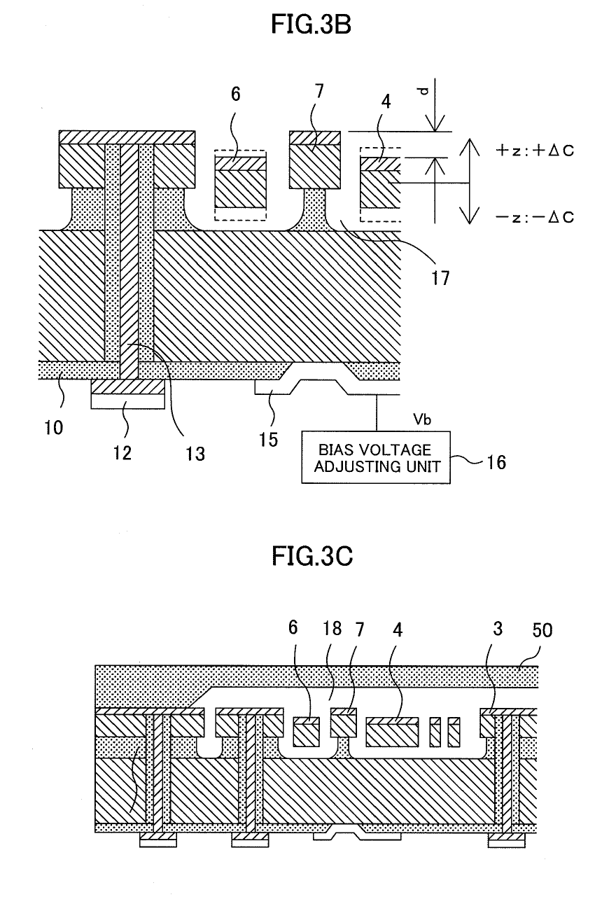

Next, an arrangement, which is a characteristic of the present invention, where the movable electrode 6 and the fixed electrode 7 in an initial offset state have different distance to the support substrate 2a will be described with reference to FIGS. 3A and 3B. The bias voltage applying unit includes the substrate electrode 15 and a bias voltage adjusting unit 16 which adjusts bias voltage VB applied to the substrate electrode 15. FIG. 3A is a sectional view, taken along line A-A′ in FIG. 1, of the acceleration sensor 1A in an initial state with a bias voltage applied to the substrate electrode 15. FIG. 3B is an enlarged view of a portion, including a pair of mutually adjacent movable electrode 6 and fixed electrode 7, of FIG. 3A. When the bias voltage VB is applied to between the movable electrode 6 and the substrate electrode 15, the movable electrode 6 is pulled toward the support substrate 2a by an electrostatic force. Namely, the bias voltage causes the movable electrode 6 to be displaced by an initial displacement of d0 toward the support substrate 2a. The fixed electrode 7 fixed to the support substrate 2a via the interlayer insulation layer 2b is not displaced. As a result, the positional relationship between the movable electrode 6 and the fixed electrode 7 changes such that the distance from the support substrate 2a to differ between the two electrodes by the initial displacement of d0. Thus, adjusting the bias voltage VB changes the positional relationship, in terms of the distance from the support substrate 2a, between the movable electrode 6 and the fixed electrode 7. The electrostatic capacitance formed between the mutually facing surface portions of the movable electrode 6 and the fixed electrode 7 in such an initial offset state is defined as an initial capacitance value C0.

When, in the initial offset state, acceleration is applied to the semiconductor physical quantity sensor causing the movable electrode 6 and the mass body 4 to be displaced in the +z direction, the areas of mutually facing surface portions of the movable electrode 6 and the fixed electrode 7 increase to cause the electrostatic capacitance between the movable electrode 6 and the fixed electrode 7 to increase. Namely, the electrostatic capacitance between the movable electrode 6 and the fixed electrode 7 increases from the initial electrostatic capacitance C0 to C0+ΔC.

When, on the other hand, acceleration is applied to the semiconductor physical quantity sensor causing the movable electrode 6 and the mass body 4 to be displaced in the −z direction, the areas of mutually facing surface portions of the movable electrode 6 and the fixed electrode 7 decrease to cause the electrostatic capacitance between the movable electrode 6 and the fixed electrode 7 to decrease. Namely, the electrostatic capacitance between the movable electrode 6 and the fixed electrode 7 decreases from the initial electrostatic capacitance C0 to C0−ΔC.

As described above, shifting the moving electrode 6 and the fixed electrode 7 formed in the same layer beforehand in the direction of displacement detection makes it possible to appropriately detect the direction and magnitude of acceleration applied to the semiconductor physical quantity sensor.

The semiconductor physical quantity sensor is preferably protected with a protective cover. FIG. 3C is a sectional view taken along line A-A′ in FIG. 1 with the sensor covered with a cap 50 joined to the upper surface of the semiconductor physical quantity sensor by anodic bonding using a glass wafer. The method of joining the cap to the sensor is not limited to the anodic glass bonding. A different method, for example, room-temperature surface-activated bonding using a silicon wafer or a method using metal adhesive (Au—Sn) may also be used. Filling nitrogen gas or inactive gas in the space covered by the cap 50 can suppress sensor characteristic variations including those attributable to aging. This makes it possible to keep sensor characteristics stable for a longer period of time.

Generally, in cases where a movable body is displaced using an electrostatic force, a pull-in phenomenon occurs when the displacement of the movable body reaches two thirds the distance before displacement between the movable body and the fixed electrode facing the movable body to generate an electrostatic force. Therefore, the maximum displacement dmax of the movable electrode 6 is limited to two thirds the distance between the movable electrode 6 and the support substrate 2a (i.e. two thirds the thickness of the interlayer insulation layer 2b). In the first embodiment, the thickness of the interlayer insulation layer 2b of the acceleration sensor 1A is 3 micrometers, so that the value of dmax is 2 micrometers. The initially required displacement value d0 will be explained in detail later in explaining the operating principle of the acceleration sensor. In most cases, the d0 value in the range of 50 nm to 1 micrometer will be appropriate. The interlayer insulation layer 2b ranges in thickness from 100 nm up to 4 micrometers with the sensor fabrication cost and productivity taken into consideration.

FIG. 4 shows the acceleration sensor 1A in a mounted state. The acceleration sensor 1A attached with a cap is mounted in a ceramic package 60 together with a signal processing IC 70. In the mounting process, first the signal processing IC 70 is fixed to the ceramic package 60 via an adhesive 80, then the acceleration sensor 1A is bonded onto the signal processing IC 70 via the adhesive 80.

Subsequently, the terminals of the signal processing IC 70, the acceleration sensor 1A, and the ceramic package 60 are connected by bonding conductive wires 90. The process is completed by sealing the acceleration sensor 1A with a lid 100.

The operating principle of the acceleration sensor 1A of the first embodiment will be explained below. In the acceleration sensor 1A, when acceleration A is applied from outside to the mass body 4, the mass body 4 is subjected to an inertial force F=mA. The inertial force is converted into a restoring force F=kz of a beam 5 (k) supporting the mass body 4; where z represents the displacement of the mass body 4.

What is described above is represented by the equation (1) shown below, where displacement z is a function of natural frequency f0 determined by mass m, which includes the movable electrodes 6 and the mass body 4, and spring constant k of the beam 5. The scales of the movable electrodes 6 and the fixed electrodes 7 are determined by displacement z, the range of acceleration to be measured, measurement resolution, and the processing capacity of the signal processing IC 70.

The acceleration sensor 1A of the first embodiment, shown in FIG. 1, has a natural frequency f0 of 3 kHz and externally measures 2 mm square as determined by taking into account what is described above.

$$z = \frac{1}{{( 2 π {f}_{0} )}^{2}} \cdot A \qquad ( 1 )$$

where:
z=displacement of movable electrodes 6 (=mass body 4)
A=acceleration applied
f₀=natural frequency of acceleration sensor 1A

$$( {f}_{0} = \frac{1}{2 π} \cdot \sqrt{\frac{k}{m}} )$$

m=mass of movable part (movable electrodes 6+mass body 4)
k=spring constant of beam 5 suspending the movable part

When an acceleration of 1 G is applied to the acceleration sensor 1A whose natural frequency f0 is 3 kHz, the movable electrodes 6 are displaced by 27.58 nm. That is, a minimum value of displacement d required to detect an acceleration of 1 G is 27.58 nm. In the first embodiment, the mass m of the movable part of the acceleration sensor 1A is 120 micrograms and the spring constant k is 43 N/m. The surface portion facing the support substrate 2a of the movable part has an area of 2.4 mm². The bias voltage required to displace the movable part by 30 nm is 0.8 V.

The electrostatic capacitance in an initial state (initial capacitance value) C0 can be adjusted by adjusting the value of bias voltage VB. In the first embodiment, a bias voltage VB of 3 V is applied to the acceleration sensor 1A in advance to set an initial displacement d0 to about 500 nm. The displacement corresponds to an acceleration of about 16G. The present invention, however, does not require the displacement to be a specific value. The value may be adjusted appropriately, for example, according to a measurement range requirement or the purpose of operation, for example, correcting sensor sensitivity variation.

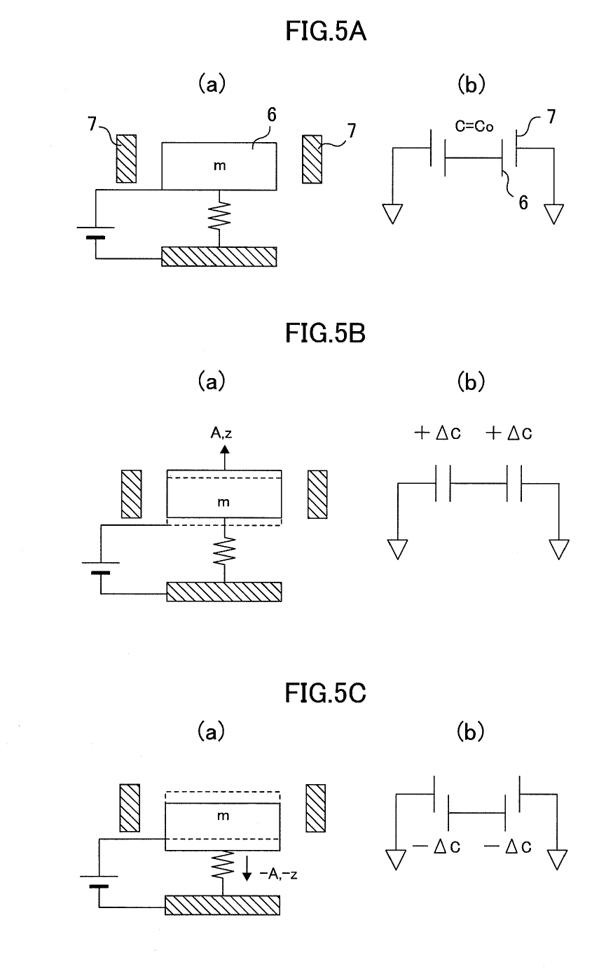

FIGS. 5A to 5C show operating states of the acceleration sensor 1A. FIG. 5A shows the acceleration sensor 1A in an initial state. FIG. 5B shows the acceleration sensor 1A in a state where upward acceleration A is applied to the sensor causing the movable electrode 6 to be displaced upward by z. FIG. 5C shows the acceleration sensor 1A in a state where downward acceleration −A is applied to the sensor causing the movable electrode 6 to be displaced downward by z. The left-half portions (a) of FIGS. 5A to 5C show positional relationships between the movable electrode 6 and the fixed electrodes 7 in the respective states. The right-half portions (b) of FIGS. 5A to 5C show changes, between the respective states (an initial state with capacitance C0 and other acceleration-applied states), in capacitance formed between the movable electrode 6 and the fixed electrodes 7.

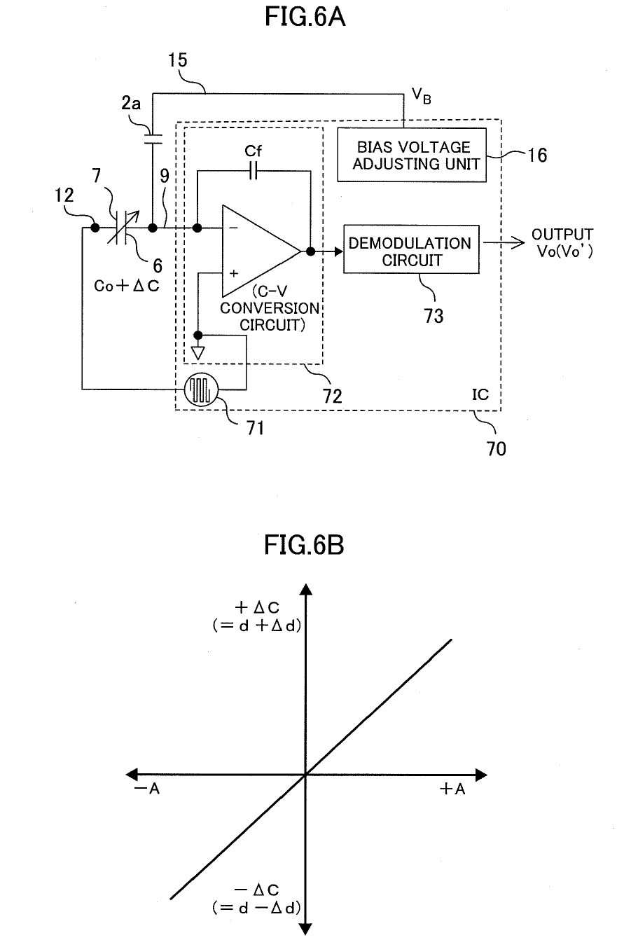

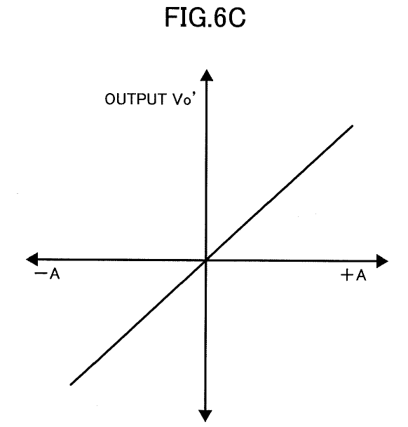

FIG. 6A is a schematic diagram of the acceleration sensor 1A and a signal processing circuit therefor, i.e. the signal processing IC 70. The signal processing IC 70 includes the bias voltage adjusting unit 16, a carrier wave generation unit 71, a C-V conversion circuit 72, and a demodulation circuit 73 including a synchronous detection circuit and an A-D conversion unit. A control device (not shown) controls other constituent elements (not shown) using an output voltage Vo determined according to the magnitude and direction of acceleration applied to the sensor. A voltage corresponding to the initial displacement and capacitance change ΔC is applied to an inverting input terminal of the C-V conversion section 72. The control device, for example, an operation control device circuit which uses output signals of the signal processing IC 70 is formed on a substrate which may be the substrate where the signal processing IC 70 is formed.

The equation (2) below is a relational expression for capacitance change ΔC caused by an analog output of the signal processing IC 70 and acceleration applied to the sensor.

$$Vo = - \frac{{C}_{0} \pm Δ C}{{C}_{f}} \cdot Vi \qquad ( 2 )$$

where:
Vo=output voltage
C0=initial capacitance between movable electrodes 6 and fixed electrodes 7
ΔC=capacitance change caused by acceleration application
Cf=reference capacitance
Vi=carrier voltage

When, for the above equation (2), the reference capacitance Cf is set to C0 (i.e. C0/Cf=1) and then the known carrier voltage Vi is subtracted, the output voltage Vo of the equation (2) becomes equal to output voltage Vo′ of the following equation (3).

$${Vo}^{′} = \frac{∓ Δ C}{( {C}_{0} = {C}_{f} )} \cdot Vi \qquad ( 3 )$$

where Vo′=output voltage after signal processing

The above equation (3) indicates that the output voltage varies with the magnitude of and the sign attached to ΔC. Hence, the direction and magnitude of acceleration applied can be determined based on the output voltage.

FIG. 6B shows relationships among the direction and magnitude of acceleration A applied, displacement d, and capacitance change ΔC. FIG. 6C shows a relationship between acceleration A and output voltage Vo′. Acceleration A and displacement d of the movable electrodes, i.e. capacitance change ΔC, are in a proportional relationship. Output voltage Vo′ proportional to acceleration A can be obtained by setting reference capacitance Cf to C0.

The above equation (3) is based on the assumption that the initial capacitance C0 between the movable electrodes and the fixed electrodes equals the reference capacitance Cf. If a difference occurs between them, the difference directly affects sensor characteristics (sensitivity and initial displacement). In a real sensor fabrication process, the gap between the movable electrodes 6 and the fixed electrodes 7 or the areas of their mutually facing surface portions often vary from sensor to sensor, so that characteristics of such acceleration sensors also vary.

Characteristic differences between acceleration sensors can be corrected by adjusting the bias voltage between the movable part and the support substrate 2a and thereby equalizing the initial capacitance C0 and the reference capacitance Cf. Namely, in the method in which an electrostatic attractive force is made use of, it is possible, while maintaining the relationship between the physical quantity to be detected and the capacitance change (ΔC) caused between the fixed electrodes and the movable electrodes, to adjust the initial capacitance value (C0) by adjusting the bias voltage.

Even though, for the foregoing equation (3), it is assumed, to make explanation easier to understand, that the initial capacitance C0 between the movable electrodes and the fixed electrodes equals the reference capacitance Cf, there may be a difference between the initial capacitance C0 and the reference capacitance Cf as long as the initial capacitance C0 is adjustable and the sensitivity or the output in an initial state (i.e. the output with an initial displacement d0 with no acceleration applied) can be adjusted by adjusting the initial capacitance C0. As is clear from FIGS. 6B and 6C, the acceleration A, the bias voltage, i.e. the capacitance change ΔC, and the output voltage Vo′ are mutually proportional, so that they can be easily adjusted.

For the acceleration sensor of the first embodiment, the initial capacitance C0 is adjusted by adjusting the bias voltage based on the relationships shown in FIGS. 6B and 6C. In this way, variations in sensitivity or initial displacement between different acceleration sensors can be adjusted. The same method in which the bias voltage is adjusted can be used to set a displacement d which equals the sum of the initial displacement d0 and a displacement adjusting value d1 determined for a particular measurement range or to make up for characteristic differences between sensors. Thus, the bias voltage can be adjusted not only to set the initial displacement but also to adjust sensitivity and characteristic differences between sensors.

Assume, for example, that: the initial capacitance C0 between the movable electrodes 6 and the fixed electrodes 7 is 2 pF; the reference capacitance Cf is 1 pF; and an additional capacitance ΔC of 200 fF is generated when an acceleration of 1 G is applied. Based on the equation (2), when the input carrier voltage is 2 V, the output voltage Vo is 4.4 V. When, in this case, Vcc (saturation voltage of operational amplifier) is 4.5 V, and an acceleration of 2 G is applied, the output voltage Vo becomes 4.8 V to be outside the measurable range.

When the initial capacitance C0 is adjusted to 1 pF by adjusting the bias voltage, the output voltage Vo is 2.2 V for an acceleration of 1 G and 3 V for an acceleration of 5 G. The capacitance change ΔC caused by an application of acceleration is 200 fF for an application of 1 G and 1 pF for an application of 5 G regardless of the initial capacitance C0.

From the foregoing, it is known that the measurement range of the acceleration sensor can be changed by adjusting the bias voltage without saturating the C-V conversion section 72.

When, in the physical quantity sensor of the present embodiment, an electrostatic force is applied to the movable electrodes in the thickness direction of the substrate (in the direction toward outside the sensor surface), the distance between the movable electrodes and the support substrate changes causing the movable electrode to be displaced in the substrate thickness direction with respect to the fixed electrodes fixed to the substrate.

Measuring the displacement makes it possible to appropriately determine the magnitude and direction of the physical quantity applied to the sensor in the displacement direction.

The physical quantity sensor of the present embodiment can be fabricated by preparing a multi-layer substrate including a support substrate on which a conductive layer (active layer) is formed via, in the substrate thickness direction, an interlayer insulation layer; movably connecting movable electrodes formed in the active layer to the support substrate via the interlayer insulation layer; and fixing fixed electrodes formed also in the active layer to the support substrate. The multi-layer substrate may be a silicon-on-insulator substrate (i.e. an SOI wafer) including the support substrate and the active layer both formed of silicon and the insulation layer formed of silicon oxide film.

In the SOI wafer, a bias voltage is applied to between the active layer on which the movable electrodes are formed and the support substrate. Therefore, a sensor structure in which the movable electrodes suspended by the support substrate via the interlayer insulation layer can be pulled toward the support substrate to be displaced in the substrate thickness direction can be realized without requiring a complicated fabrication process. The SOI wafer can be fabricated without involving a high-temperature process, so that it offers high flexibility as to circuit mixing and process selection.

The initial displacement of the movable electrodes is a function of the voltage applied, the areas of mutually facing surface portions of the movable and fixed electrodes, and the spring constant in the z direction of the movable electrodes, and is not related with the thickness of the active layer. Characteristics of the physical quantity sensor can therefore be set arbitrarily and actively.

In the physical quantity sensor of the present embodiment, the movable electrodes are displaced toward the support substrate beforehand thereby reducing the gap between the movable electrodes and the support substrate. This generates a damping effect against vibrations of the movable electrodes and improves the vibration resistance of the sensor when subjected to external disturbance.

### Second Embodiment

Next, a semiconductor physical quantity sensor according to a second embodiment of the present invention will be described. The second embodiment is modified in the part of electrodes of the first embodiment. According to the second embodiment of the present invention, the electrodes (the movable electrodes 6 and the fixed electrodes 7) are formed on the cap 50 (See FIG. 3C) instead of forming on the support substrate 2a. In the following, description already provided regarding the first embodiment will be omitted to avoid duplication. In this case, the movable electrodes 6 can be displaced away from the support substrate 2a by applying a bias voltage to between the cap 50 and the movable electrodes 6.

When the movable electrodes 6 are displaced away from the support substrate 2a by applying a bias voltage to between the cap 50 and the movable electrodes 6, the displacement is not restricted by the thickness of the interlayer insulation layer 2b. It is therefore possible to appropriately adjust the initial displacement d0 and the displacement adjusting value d1 as required by taking into account the magnitude of the applicable bias voltage.

According to the second embodiment, the movable electrodes are displaced away from the support substrate, so that the displacement is not restricted by the thickness of the interlayer insulation layer or by any pull-in phenomenon. It is therefore possible to reduce the initial capacitance C0 between the movable electrodes and the fixed electrodes while maintaining the capacitance change (ΔC) caused by a physical quantity applied to the sensor. This makes it possible to detect the applied physical quantity with high sensitivity and high accuracy.

### Third Embodiment

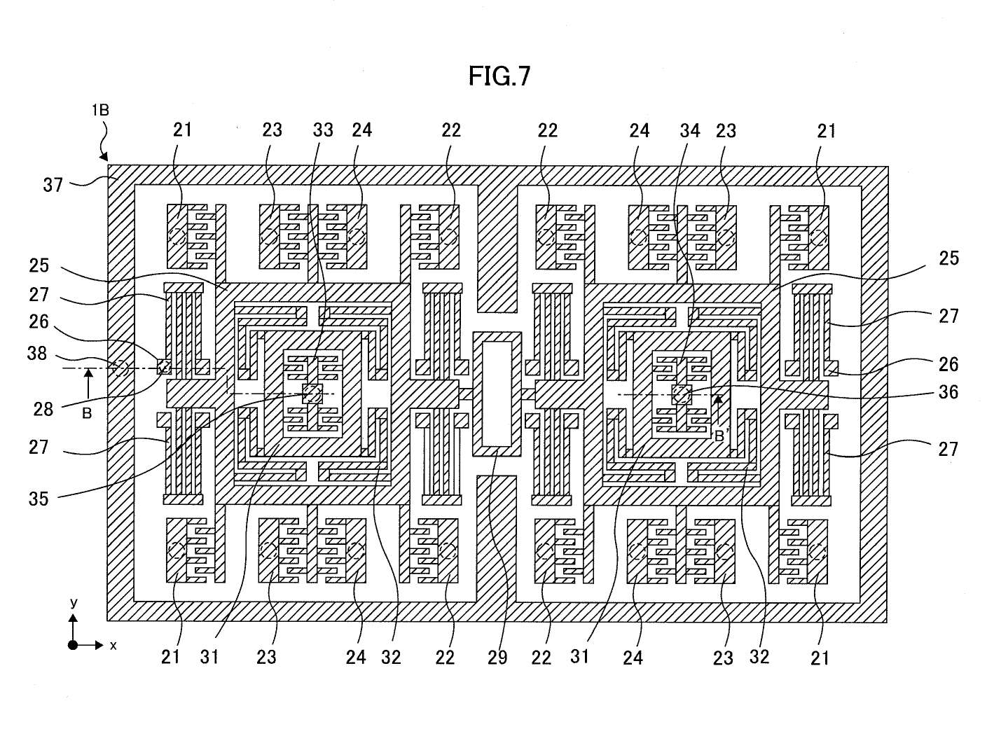

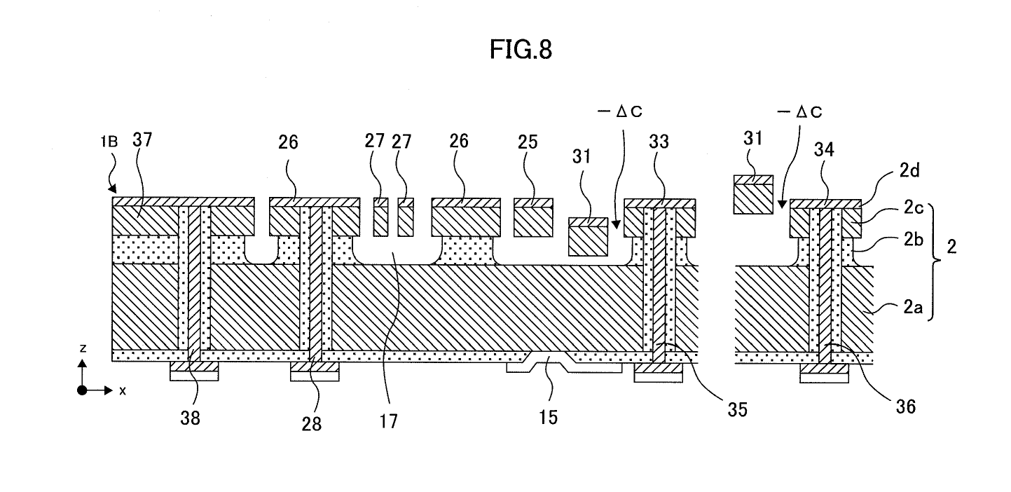

The semiconductor physical quantity sensor according to a third embodiment of the present invention is an angular rate sensor for detecting an angular rate as a physical quantity. The structure and the principle of operation of an angular rate sensor 1B will be described in detail below with reference to drawings. In the following, description already provided regarding the first embodiment will be omitted to avoid duplication. FIG. 7 is a schematic diagram showing a plan view of principal constituent elements of the angular rate sensor 1B of the third embodiment. FIG. 8 shows a sectional view taken along line B-B′ in FIG. 7.

The angular rate sensor 1B of the third embodiment includes, broadly classified, two driven elements 25 and two Coriolis elements 31. The driven elements 25 each include driving electrodes 21 and 22 which drive the sensor and monitoring electrodes 23 and 24 which monitor the driving amplitude of the sensor. The Coriolis elements 31 are displaced by angular rate application and respectively include detection electrodes 33 and 34 which detect capacitance changes caused by the displacement.

The driven elements 25 that drive the sensor and generate a driving amplitude will be described below. On the SOI substrate, fixed parts 26 are, as shown in FIGS. 7 and 8, formed on the active layer 2c and fixed to the support substrate 2a. The fixed parts 26 each include a through-electrode 28 for exchanging electrical signals with movable parts (e.g. a driven element 25 and a Coriolis element 31) and are each connected with supporting beams 27 for supporting the driven element 25. The supporting beams 27 are designed to be flexible in the x direction, i.e. the excitation direction, and rigid in the z direction, i.e. the detection direction.

The driven elements 25 are supported by the supporting beams 27 in a state of being suspended off the support substrate 2a with the interlayer insulation layer 2b removed.

The driven elements 25 each include movable electrodes which face the driving electrodes 21 and 22 and the monitoring electrodes 23 and 24 to form capacitance between such electrodes and themselves. The driving electrodes 21 and 22 have mutually reverse-phased driving signals inputted to them and drive the driven elements 25. The two driven elements 25 are linked to each other via a link beam 29. The two driven elements 25 are therefore vibrated in mutually reversed mode. The frequency of the driving signals is aligned with the reversed mode frequency (the second natural frequency in the case of the angular rate sensor of the present embodiment) of the driven elements 25 so as to obtain a large amplitude using a small driving energy.

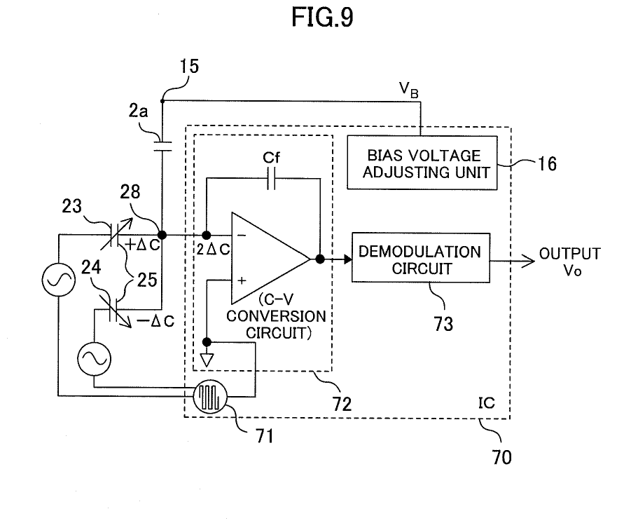

The monitoring electrodes 23 and 24 are for measuring the vibration amplitudes of the driven elements 25. They exchange electrical signals with the external signal processing IC 70 via through-electrodes. FIG. 9 shows a driving amplitude monitoring circuit. In FIG. 9, circuit elements equivalent to elements shown in FIGS. 7 and 8 are denoted by the same reference numerals as those denoting the corresponding elements shown in FIGS. 7 and 8. To monitor the vibration amplitude, the circuit applies mutually reverse-phased carrier waves to the monitoring electrodes 23 and 24 and converts, at the C-V conversion circuit 72 of the signal processing IC 70, the capacitance change corresponding to the driving amplitude into a voltage signal. As already well-known, the monitored signal can be fed back to the driving electrodes 21 and 22 so as to keep the vibration amplitude constant (automatic gain control). This known technique will not be describer further in this specification.

The Coriolis elements 31 are each connected to one of the driven elements 25 with four detection beams 32 which are rigid in the y direction perpendicular to each of the excitation direction x and the detection direction z and flexible in the z direction, i.e. the detection direction. Each of the Coriolis elements 31, therefore, vibrates, following the vibration in the x direction of the corresponding driven element 25, in the excitation direction in the same phase as the driven element 25. The amplitudes in the excitation direction x of the Coriolis elements 31 can be made the same as the amplitudes of the driven elements 25 by increasing the rigidity in the x direction of the detection beams 32, or they can be made larger or smaller than the amplitudes of the driven elements 25 by adjusting the rigidity proportion among the detection beams 32, supporting beams 27, and the link beam 29. Namely, regarding the x direction, a mass-spring system including a driven element 25 and a Coriolis element 31 as masses and the supporting beams 27, the link beam 29, and the detection beams 32 as springs may be arranged as a single-degree-of-freedom system or as a two-degree-of-freedom system for use in first-order mode.

The Coriolis elements 31 are suspended by the driven elements 25 and are driven in mutually reversed phases. Therefore, the Coriolis force generated when an angular rate about the y axis is applied to the angular rate sensor 1B causes the Coriolis elements 31 to vibrate in mutually reversed phases.

Detection electrodes 33 and 34 face the Coriolis elements 31, respectively, and electrostatic capacitance is formed between them. Like in the case of the monitoring electrodes 23 and 24, reverse-phased carrier waves are applied to the detection electrodes 33 and 34 via through-electrodes 35 and 36, respectively. Therefore, when, with an angular rate applied to the sensor, the Coriolis elements 31 are vibrated in mutually reversed phases, capacitance changes associated with the detection electrodes 33 and 34 can be differentially detected. The circuit to detect the capacitance changes is similar to that, shown in FIG. 9, for the monitoring electrodes, so that it will not be described here.

In cases where the detection electrodes 33 and 34 and the Coriolis elements 31 are positioned without being shifted, however, applying an angular rate to the sensor causing the Coriolis elements 31 to be displaced in mutually opposite directions causes the areas of mutually facing surfaces portions of the movable electrodes and the fixed electrodes to decrease for both of the detection electrodes 33 and 34, so that the capacitance reduces by AC (i.e. a change of −ΔC) both between the detection electrode 33 and one of the Coriolis elements 31 and between the detection electrode 34 and the other of the Coriolis elements 31 as shown in FIG. 8 showing a sectional view taken along line B-B′ in FIG. 7. In the differential detection circuit shown in FIG. 9, therefore, the capacitance changes associated with the detection electrodes 33 and 34 cancel each other to generate no output.

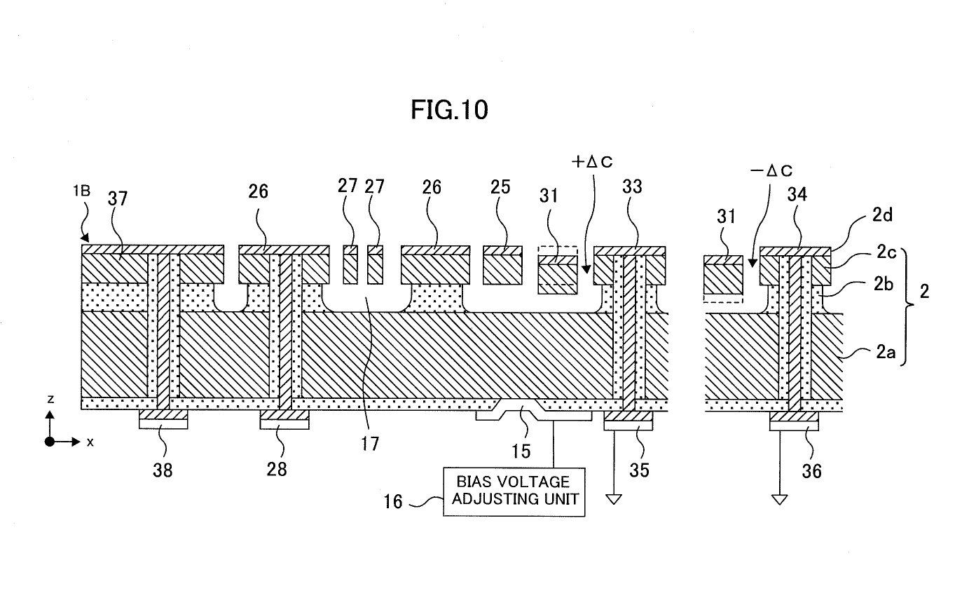

FIG. 10 is a sectional view of a state in which, like in the forgoing first embodiment, a bias voltage V_{B} is applied to between the movable parts (the driven elements 25 and the Coriolis elements 31) and the support substrate 2a via the substrate electrode 15 causing the Coriolis elements 31 to be displaced toward the substrate 2a. Even though the driven elements 25 are also subjected to an electrostatic force generated by the bias voltage application and directed toward the support substrate 2a, the resultant displacements of the driven elements 25 are negligibly small with the supporting beams 27 designed as springs which are flexible in the x direction, i.e. the excitation direction and rigid in the z direction, i.e. detection direction.

When, in a state where the Coriolis elements 31 are displaced toward the support substrate 2a with respect to the fixed detection electrodes 33 and 34 (as illustrated in solid line in FIG. 10), an angular rate is applied to the sensor, the Coriolis elements 31 are displaced in mutually opposite directions causing capacitance changes of +ΔC and −ΔC for the detection electrodes 33 and 34, respectively.

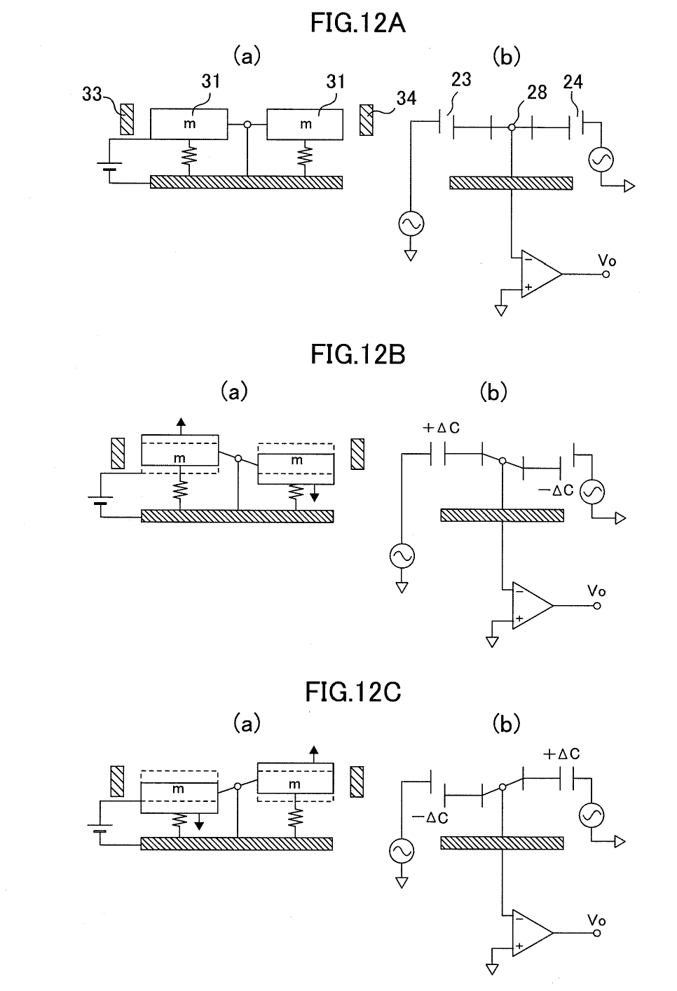

The left-half portions (a) of FIGS. 12A to 12C show operating states of the angular rate sensor of the third embodiment. In the third embodiment, too, the output voltage V0 proportional to the angular rate applied to the sensor can be obtained using the detection circuit shown in FIG. 9. The following equation (4) represents the output voltage V0.

$$Vo = \frac{2 Δ C}{{C}_{f}} \cdot Vi \qquad ( 4 )$$

The driven elements 25, the Coriolis elements 31, and other elements of the sensor are surrounded, like in the case of the acceleration sensor 1A of the first embodiment, by a dummy pattern 37 kept at a predetermined potential via a through-electrode 38.

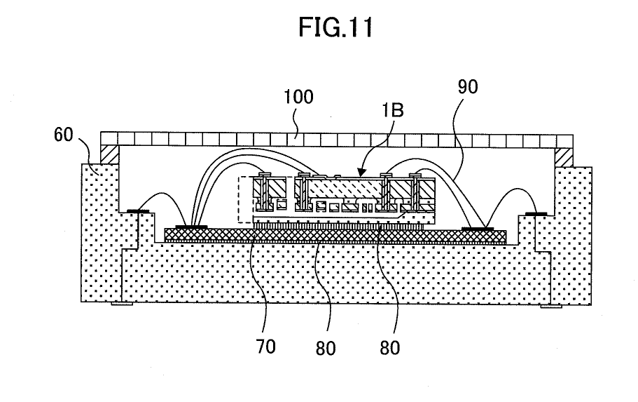

FIG. 11 is a schematic view of the angular rate sensor 1B and a signal processing circuit thereof, i.e. the signal processing IC 70. The angular rate sensor 1B attached with a cap is mounted in a ceramic package 60 together with the signal processing IC 70. When mounting them in the ceramic package 60, first the signal processing IC 70 is fixed to the package via an adhesive 80, then the angular rate sensor 1B is bonded onto the signal processing IC 70 via the adhesive 80. Subsequently, the terminals of the signal processing IC 70, the angular rate sensor 1B, and the ceramic package 60 are connected by bonding conductive wires 90. The process is completed by sealing the angular rate sensor 1B with a lid 100. A control device circuit, for example, the circuit of a travel speed control device which uses signals outputted from the signal processing IC is formed on the substrate where the signal processing IC 70 is formed or on a different substrate.

In the angular rate sensor of the third embodiment, a voltage corresponding to the capacitance change +ΔC or −ΔC caused by an angular rate applied to the sensor is applied, as shown in the right-half portions (b) of FIGS. 12A to 12C, to the input side (inverting input terminal) of the C-V conversion circuit included in the signal processing IC 70.

As in the second embodiment, it is possible, though not illustrated, to displace the Coriolis elements 31 away from the support substrate 2a by installing the movable and fixed electrodes on a cap 50 and applying a bias voltage to between the movable parts (the driven elements 25 and the Coriolis elements 31) and the cap 50. The effects of displacing the Coriolis elements 31 away from the support substrate 2a are the same as those of displacing the

Coriolis elements 31, as described above, toward the support substrate 2a.

The present embodiment can produce effects similar to those produced by the first and the second embodiment.

The invention made by the present inventors has been described in detail based on embodiments. The present invention, however, is not limited to the above embodiments, and it can be modified in various ways without departing from the scope and spirit of the invention.

What is claimed is:

1. A semiconductor physical quantity sensor comprising a movable electrode which is displaced when a physical quantity is applied and a fixed electrode which faces the movable electrode and forms electrostatic capacitance, the semiconductor physical quantity sensor detecting, when a physical quantity is applied thereto, the physical quantity according to an electrostatic capacitance change caused between the movable electrode and the fixed electrode,
wherein the movable electrode and the fixed electrode are formed on a same conductive layer having a substantially uniform height on a substrate, and
wherein the movable electrode and the fixed electrode are placed, using an electrostatic force, in an initial offset state where the movable electrode and the fixed electrode have different distances to the substrate.

2. The semiconductor physical quantity sensor according to claim 1 comprises a multi-layer substrate which includes an active layer is formed, via an interlayer insulation layer, on a support substrate,
wherein the movable electrode is formed on the active layer and is movably linked to the support substrate,
wherein the fixed electrode is formed on the active layer and is fixed to the support substrate, and
wherein the multi-layer substrate is a silicon-on-insulator substrate in which the support substrate and the active layer are formed of silicon and the interlayer insulation layer is formed of silicon oxide film.

3. The semiconductor physical quantity sensor according to claim 2,
wherein the movable electrode and the fixed electrode have a same distance to the support substrate when no external force is applied, and
wherein the initial offset state is entered by displacing the movable electrode toward the support substrate using the electrostatic force generated by applying a bias voltage to between the support substrate and the active layer.

4. The semiconductor physical quantity sensor according to claim 2,
wherein, on the multi-layer substrate, a cap made of glass or silicon is disposed, and
wherein the initial offset state is entered by applying a bias voltage to between the cap and the movable electrode and thereby displacing the movable electrode away from the support substrate.

5. The semiconductor physical quantity sensor according to claim 3, comprising a unit which can adjust a magnitude of the bias voltage.

6. The semiconductor physical quantity sensor according to claim 5,
wherein a measurement range and the initial offset state can be adjusted by adjusting the magnitude of the bias voltage.

7. The semiconductor physical quantity sensor according to claim 5,
wherein sensitivity and an initial output of the semiconductor physical quantity sensor can be adjusted relative to another semiconductor physical quantity sensor by adjusting the magnitude of the bias voltage.

8. The semiconductor physical quantity sensor according to claim 1,
wherein an acceleration in a direction toward outside a sensor surface plane is detected based on a change in the electrostatic capacitance between the movable electrode and the fixed electrode.

9. The semiconductor physical quantity sensor according to claim 1,
wherein an angular rate in a direction toward outside a sensor surface plane is detected based on a change in the electrostatic capacitance between the movable electrode and the fixed electrode.

10. A semiconductor physical quantity sensor, comprising:
a fixed electrode formed via an insulation layer on a substrate;
a movable electrode separated from the substrate by a gap and formed to be substantially as high as the fixed electrode; and
a bias voltage application unit which places, using an electrostatic force, the movable electrode and the fixed electrode in an initial offset state where the movable electrode and the fixed electrode have different distances to the substrate;
wherein a physical quantity applied is detected based on a change in electrostatic capacitance between mutually facing surface portions of the movable electrode and the fixed electrode.

11. The semiconductor physical quantity sensor according to claim 10,
wherein the fixed electrode and the movable electrode are formed in a common active layer, and
wherein the substrate is a silicon-on-insulator substrate in which a support substrate and the active layer are formed of silicon and the insulation layer is formed of silicon oxide film.

12. The semiconductor physical quantity sensor according to claim 10 comprises a multi-layer substrate which includes an active layer formed, via an interlayer insulation layer, on the support substrate,
wherein the movable electrode is formed on the active layer and is movably linked to the support substrate, and
wherein the fixed electrode is formed on the active layer and is fixed to the support substrate.

13. The semiconductor physical quantity sensor according to claim 10,
wherein the bias voltage application unit includes a bias voltage adjusting unit which actively adjusts an amount of displacement between the fixed electrode and the movable electrode.

14. The semiconductor physical quantity sensor according to claim 13,
wherein the bias voltage adjusting unit has a function to adjust sensitivity and an initial output of the semiconductor physical quantity sensor relative to another semiconductor physical quantity sensor.

15. The semiconductor physical quantity sensor according to claim 12,
wherein, on the multi-layer substrate, a cap formed of glass or silicon is provided for covering the active layer, and
wherein nitrogen gas or inactive gas is filled in space covered by the cap.

16. The semiconductor physical quantity sensor according to claim 12,
wherein, on the multi-layer substrate, a cap made of glass or silicon is disposed,
wherein the movable electrode and the fixed electrode are formed on the cap, and
wherein, in the initial offset state, the movable electrode is displaced away from the support substrate by applying a bias voltage to between the cap and the movable electrode.

17. A control device provided with a semiconductor physical quantity sensor, the semiconductor physical quantity sensor being mounted in a ceramic package together with a signal processing IC,
wherein the semiconductor physical quantity sensor includes a movable electrode to be displaced when a physical quantity is applied and a fixed electrode facing the movable electrode and forming electrostatic capacitance and, when a physical quantity is applied, detects the physical quantity based on a change in electrostatic capacitance between the movable electrode and the fixed electrode,
wherein the movable electrode and the fixed electrode are formed on a same conductive layer having a substantially uniform height on a substrate,
wherein the signal processing IC includes a bias voltage adjusting unit which adjusts a bias voltage applied to generate an electrostatic force for placing the movable electrode and the fixed electrode in an initial offset state where the movable electrode and the fixed electrode have different distances to the substrate, and
wherein the signal processing IC outputs a voltage corresponding to a direction and magnitude of a physical quantity applied to the semiconductor physical quantity sensor.

18. The control device provided with a semiconductor physical quantity sensor according to claim 17,
wherein the signal processing IC has a C-V conversion section which converts the change in electrostatic capacitance into a change in voltage, and
wherein, when C0 is an initial capacitance corresponding to the initial offset state of the movable electrode and the fixed electrode, ΔC is a capacitance change caused by application of a physical quantity, Cf is a reference capacitance supplied to the C-V conversion section, Vi is a carrier voltage inputted to the C-V conversion section, and Vo′ is an output voltage of the C-V conversion section,
the output voltage Vo′ corresponding to the physical quantity applied is calculated, with the reference capacitance Cf set to be equal to the initial capacitance C0, based on the equation (3).
$${Vo}^{′} = \frac{∓ Δ C}{( {C}_{0} = {C}_{f} )} \cdot Vi \qquad ( 3 )$$

19. The control device provided with a semiconductor physical quantity sensor according to claim 18,
wherein the signal processing IC adjusts sensitivity and initial output variation of the semiconductor physical quantity sensor by adjusting the bias voltage thereby adjusting the initial capacitance C0.

20. The control device provided with a semiconductor physical quantity sensor according to claim 17,
wherein the signal processing IC includes a bias voltage adjusting unit, a carrier generating unit, and a demodulation circuit having a C-V conversion unit, a synchronous detection circuit and an A-D conversion unit.
